(19) United States
(12) Patent Application Publication
(10) Pub. No.: US 2010/0116341 A1
(43) Pub. Date: May 13, 2010

(54) Copper-gallium allay sputtering target, method for fabricating the same and related applications

(75) Inventors: Wei-Chin Huang, Tainan (TW); Cheng-Hsin Tu, Tainan (TW)

Correspondence Address: POSZ LAW GROUP, PLC, 12040 SOUTH LAKES DRIVE, SUITE 101, RESTON, VA, 20191, US

(73) Assignee: SOLAR APPLIED MATERIALS TECHNOLOGY CORP., Tainan (TW)

(21) Appl. No.: 12/292,067

(22) Filed: Nov. 12, 2008

(51) Int. Cl. C23C 14/34; C22F 1/08; B22F 3/10; B22D 13/00; C21D 1/00; B22F 3/24; C22C 9/00; H01L 31/04

(52) U.S. Cl. 136/262; 204/298.13; 148/680; 148/514; 148/554; 148/539; 419/29; 419/28; 420/489

(57) ABSTRACT

A method for fabricating a copper-gallium alloy sputtering target comprises forming a raw target; treating the raw target with at least one thermal treatment between 500° C.˜850° C. being mechanical treatment, thermal annealing treatment for 0.5˜5 hours or a combination thereof to form a treated target; and cooling the treated target to a room temperature to obtain the copper-gallium alloy sputtering target that has 71 atomic % to 78 atomic % of Cu and 22 atomic % to 29 atomic % of Ga and having a compound phase not more than 25% on its metallographic microstructure. Therefore, the copper-gallium alloy sputtering target does not induce micro arcing during sputtering so a sputtering rate is consistent and forms a uniform copper-gallium thin film. Accordingly, the copper-gallium thin film possesses improved quality and properties.

### BACKGROUND OF THE INVENTION

1. Field of Invention

The present invention relates to a method for fabricating a sputtering target, and more particularly to a method for fabricating a copper-gallium alloy sputtering target comprising a solid-solution phase principally.

2. Description of the Related Art

Non-renewable fuels are being exhausted, with peak oil, coal and gas approaching and nuclear requiring0 significant clean up costs, development of renewable energy is increasingly important. Photovoltaic solar cells, convert solar radiation directly into electricity for later use and include wafer type solar cells and thin-film type solar cells. Wafer type solar cells are current market leaders but have an indirect band gap for absorbing light, so a thick substrate layer of silicon (Si) is required. Since quantities of silicon are also limited, and the thick substrate raises production costs and practical usage, thin-film type solar cells are preferred in many instances, and may be formed as a thin layer on other materials and may be implemented as windows or the like. Thin film type solar cells include compositions of copper (Cu), gallium (Ga), indium (In) and selenium (Se) and are named after their constituent parts, copper-indium-selenium (CIS solar cells), copper-indium-gallium-selenium (CIGS solar cells) and the like.

CIGS forms an absorbing layer. Because CIGS is a direct band gap material which has high photovoltaic conversion efficiency, so it is adaptable for use as absorbing layer for solar cells.

A CIGS thin film can be produced by chemical vapor deposition (CVD) with reference to U.S. Pat. No. 5,474,939, physical vapor deposition (PVD), co-evaporation with reference to U.S. Pat. No. 5,141,564, liquid phase deposition (LPE) or the like. PVD may use sputtering to form the thin film in CIGS solar cell. Sputtering comprises forming a sputter target and a substrate, then sputtering the sputter target onto the substrate.

The CIGS thin film can also be produced by a selenization procedure as disclosed in JP10-135495, wherein an absorbent layer such as CIG is selenized to form the CIGS thin film. The sputter target can be produced by powder metallurgy or casting. When powder metallurgy is used, because gallium and indium both have low melting points, they are hard to be sintered. Furthermore, a procedure for retrieving target residues is complicated, which increases cost of production of the sputter target. When casting is used, melting points of copper, indium, gallium and selenium vary greatly, from 1083° C. for copper to 29.8° C. for gallium, so those materials do not precipitate to form a non-uniform thin film.

The CIGS thin film can also be produced by selenization as disclosed in JP110-135495, wherein an absorbent layer such as CIG is selenized to form the CIGS thin film.

Vacuum induction melting (VIM) is used to produce a conventional Cu alloy target such as Cu—In—Ga target or Cu—Ga target, wherein a eutectic microstructure of copper-alloy target includes a solid solution phase and a compound phase, wherein the compound phase is usually about 30˜40% on a metallurgical microstructure of the copper-alloy target. However, such microstructure of the copper-alloy target has the following disadvantages:

(1) the copper target has non-uniform distribution of materials, resulting in macro segregation or micro segregation;

(2) two phases of the copper-alloy target result in a non-uniform thin film with poor properties (such as light-electricity conversion efficiency and the like);

(3) two phases of the Cu alloy target induce micro arcing during sputtering, which results in a thin film with poor quality.

Therefore, a cost of production and efficiency of the CIGS solar cell is dependent on the sputter target.

To overcome the shortcomings, the present invention provides method for fabricating a copper-gallium alloy sputtering target to mitigate or obviate the aforementioned.

### SUMMARY OF THE INVENTION

The primary objective of the present invention is to provide a method for fabricating a copper-gallium alloy sputtering target comprising a solid-solution phase principally.

To achieve the objective, the method for fabricating a copper-gallium alloy sputtering target in accordance with the present invention comprises forming a raw target; treating the raw target with at least one thermal treatment between 500° C.˜850° C., which may be at least one thermal mechanical treatment, at least one thermal annealing treatment for 0.5˜5 hours or a combination thereof to form a treated target; and cooling the treated target to room temperature to obtain the copper-gallium alloy sputtering target that has 71 atomic % to 78 atomic % of Cu and 22 atomic % to 29 atomic % of Ga and having a compound phase not more than 25% on its metallurgical microstructure.

Therefore, the copper-gallium alloy sputtering target does not induce micro arcing during sputtering, allowing a consistent sputtering rate to form a uniform copper-gallium thin film. Accordingly, the copper-gallium thin film possesses improved quality and properties.

Other objectives, advantages and novel features of the invention will become more apparent from the following detailed description when taken in conjunction with the accompanying drawings.

### BRIEF DESCRIPTION OF THE DRAWINGS

FIG. 1 is a phase diagram of a copper-gallium (Cu—Ga) alloy of a conventional Cu—Ga alloy target;

FIG. 2 is a metallurgical micrograph of a conventional Cu—Ga alloy target in accordance with the prior art;

FIG. 3 is a metallurgical micrograph of a Cu—Ga alloy target in example 1 in accordance with the present invention; and

FIG. 4 is a metallurgical micrograph of a Cu—Ga alloy target in example 2 in accordance with the present invention.

### DETAILED DESCRIPTION OF THE INVENTION

As used herein, “compound” is a substance consisting of two or more different elements chemically bonded together in a fixed proportion by mass. Compounds have different physical and chemical properties from their constituent elements.

As used herein, “solid solution” is a solid-state solution of one or more solutes in a solvent. Such a mixture is considered a solution rather than a compound when the crystal structure of the solvent remains unchanged by addition of the solutes, and when the mixture remains in a single homogeneous phase.

As used herein, “reduction ratio” is the ratio of thickness variation to feed thickness of a bulk material for a mechanical operation.

A method for fabricating a copper-gallium alloy sputtering target in accordance with the present invention comprises forming a raw target; treating the raw target with at least one thermal treatment between 500° C.˜850° C. thermal annealing treatment to form a treated target; and cooling the treated target to room temperature to obtain the copper-gallium alloy sputtering target that has 71 atomic % to 78 atomic % of Cu and 22 atomic % to 29 atomic % of Ga and having a compound phase not more than 25% on its metallurgical microstructure.

Forming the raw target may comprise forming the raw target using powder metallurgy or casting may be using vacuum melting, continuous casting, centrifugal casting, hot-press sintering, hot isostatic pressing (HIP), hot plastic forming or the like.

The at least one thermal treatment may be at least one mechanical treatment between 500° C.˜850° C., at least one thermal annealing treatment between 500° C.˜850° C. for 0.5˜5 hours or a combination thereof to form a treated target.

In one aspect, the at least one thermal treatment consists of treating the raw target with at least one thermal mechanical treatment.

In another aspect, the at least one thermal treatment consists of treating the raw target with at least one thermal annealing treatment.

In another aspect, the at least one thermal treatment consists of treating the raw target with at least one thermal mechanical treatment, then treating the raw target with at least one thermal annealing treatment.

In another aspect, the at least one thermal treatment consists of treating the raw target with at least one thermal annealing treatment, then treating the raw target with at least one thermal mechanical treatment.

In another aspect, the at least one thermal treatment consists of treating the raw target with at least one mechanical treatment, then treating the raw target with at least one thermal annealing treatment then repeatedly treating the raw target with multiple thermal mechanical treatments.

Combinations of the above aspects may be altered to attain a preferred balance between cost of treatment and desired sputtering target.

Preferably, the thermal mechanical treatment comprises forging, rolling or hot pressing. Preferably, a reduction ratio during thermal mechanical treatment is 0˜90%.

More preferably, a reduction ratio during thermal mechanical treatment is 0˜50%.

Most preferably the thermal treatment comprises at least one rolling at 800° C. at a reduction rate of 25% and at least one thermal annealing treatment at 700° C. for 1 hour to attain a high ratio of solid-solution phase to compound phase.

Cooling the treated target comprises using air (air-cooling), water (water-cooling) or oil (oil-cooling).

The copper-gallium alloy sputtering target in accordance with the present invention comprises a copper-gallium alloy that has 71 atomic % to 78 atomic % of Cu and 22 atomic % to 29 atomic % of Ga and having a compound phase not more than 25% on its metallurgical microstructure.

Preferably, an average grain size in the alloy of the target is less than 1 mm.

The present invention is also related to a copper-gallium thin film being deposited using the copper-gallium alloy sputtering target.

The present invention is further related to a solar cell that comprises the copper-gallium thin film.

Because the compound phase of the copper-gallium alloy sputtering target is not more than 25% on its metallographic microstructure, the microstructure substantially presents a single phase. Therefore, the copper-gallium alloy sputtering target does not induce micro arcing during sputtering so yields a consistent sputtering rate and forms a uniform copper-gallium thin film. Accordingly, the copper-gallium thin film possesses improved quality and properties.

In the following examples, the sputtering target was analyzed by using etching solution including HNO₃, H₂O₂ and water in a ratio of 3:1:1, to calculate a ratio of a compound phase and a solid-solution phase, a micrograph being taken using an Olympus BH microscope as made by Olympus, wherein the solid-solution phase is shown by light gray and the compound phase is shown by dark gray. A ratio of the solid-solution phase to the compound phase is calculated by image measurement software, Image-Pro Plus Version 6.3 as provided by MediaCybernetics, according to equation land was calculated by image measurement software, Image-Pro Plus Version 6.3.

$$\frac{compound phase [ B ]}{solid \text{-} solution phase [ A ] + compound phase [ B ]} \qquad Equation 1$$

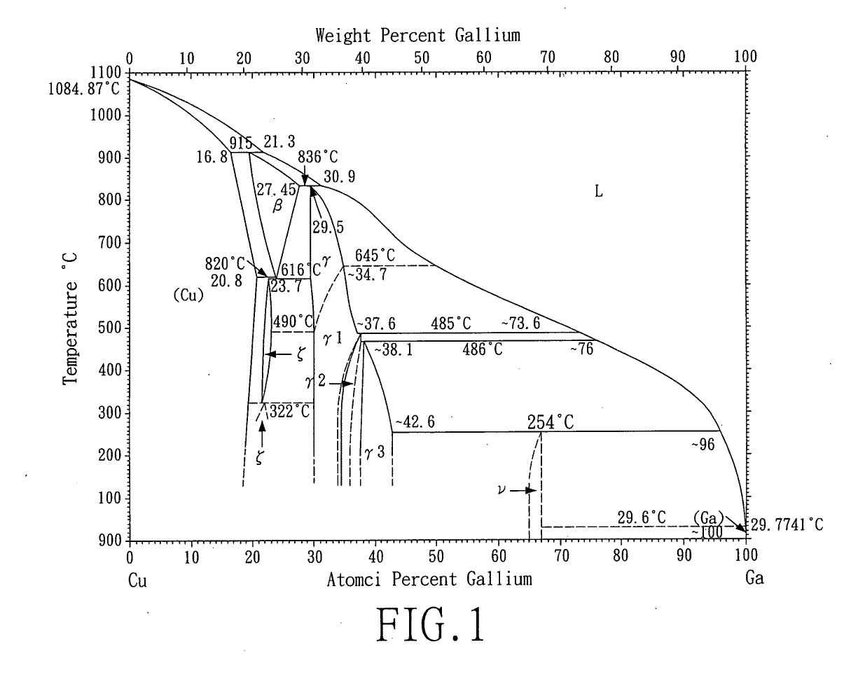

With reference to FIG. 1, showing a phase diagram of Cu—Ga alloy of a conventional Cu—Ga alloy target being a eutectic system including a solid solution phase (β phase) and a compound phase (γ phase). A theoretical ratio of the compound phase and the solid-solution phase is calculated by equation 1, yielding 30˜40%, wherein A is the β phase and B is the γ phase, so the compound phase is usually about 30˜40% on the metallographic microstructure of the Cu alloy target.

Another conventional Cu—Ga alloy sputter target comprises 75 wt % of copper and 25 wt % of gallium, which is fabricated by casting.

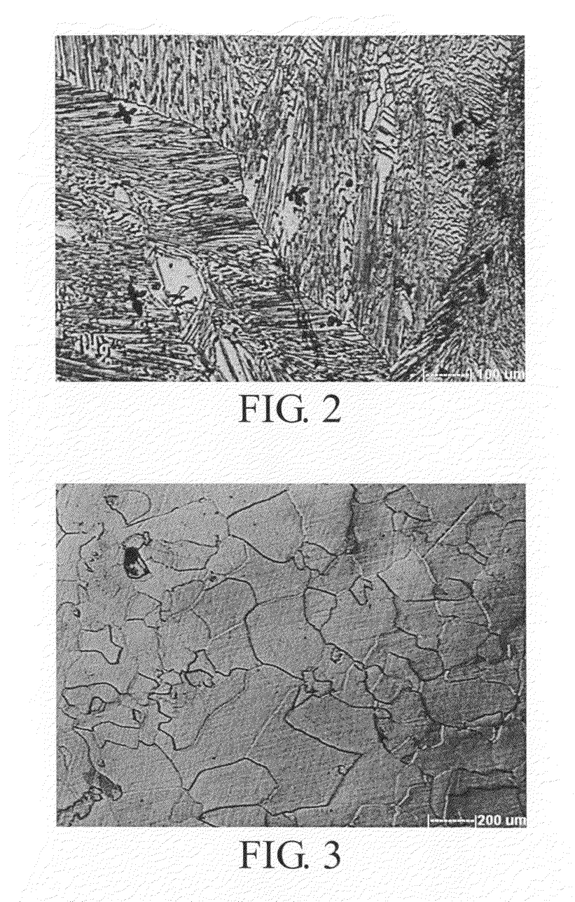

With reference to FIG. 2, wherein the solid solution phase is shown by light gray and the compound phase is shown by dark gray. The empirical ratio as calculated by by equation 1 is 30.4%; therefore, the empirical ratio is consistent with the theoretical ratio.

The method of the present invention relates to solid-state phase transformation and atom diffusion of Cu—Ga alloy, which affects the ratio of the compound phase and the solid-solution phase on it microstructure of the copper-gallium alloy sputtering target. Therefore, regardless of whether the raw target is formed by powder metallurgy or casting, after the method of the present invention, the copper-gallium alloy sputtering target substantially comprising the solid-solution phase is obtained as shown in FIG. 3.

### EXAMPLE

The following examples present methods of heat treatment of the present invention for fabricating Cu—Ga alloy sputtering targets and compare those Cu—Ga alloy sputtering targets. Each target before treatment was shown to have an empirical ratio of around 35%. Such examples are illustrative only, and no limitation on present invention is meant thereby.

### Example 1

A raw target was formed by vacuum melting. The raw target was treated by rolling at 800° C. at a reduction ratio of 25%, then was treated by thermal annealing treatment at 700° C. for 1 hour and cooled to room temperature to form a Cu—Ga alloy sputtering target.

### Example 2

A raw target was formed by air melting. The raw target was treated by thermal annealing treatment at 800° C. for 1 hour and then was treated by rolling at 800° C. at a reduction ratio of 25% then cooled to room temperature to form a Cu—Ga alloy sputtering target.

### Example 3

A raw target was formed by vacuum melting. The raw target was treated by hot-press sintering at 600° C. then was treated by thermal annealing treatment at 800° C. for 1 hour, before being cooled to room temperature to form a Cu—Ga alloy sputtering target.

### Example 4

A raw target was formed by vacuum melting. The raw target was treated by rolling at 700° C. at a reduction ratio of 40% then was cooled to room temperature to form a Cu—Ga alloy sputtering target.

### Example 5

A raw target was formed by vacuum melting. The raw target was treated by thermal annealing treatment at 700° C. for 3 hours and cooled to room temperature to form a Cu—Ga alloy sputtering target.

### Example 6

### Comparative Example

A raw target was formed by vacuum melting. The raw target was treated by rolling at 400° C. at a reduction ratio of 25% then was cooled to room temperature to form a Cu—Ga alloy sputtering target.

TABLE 1
Conditions and results of examples

| | | | B/(A + B) | B/(A + B) |
|---|---|---|---|---|
| Ex | TMT | TA | (raw target) | (target) |
| 1 | Rolling | Temp: 700° C. | ~35% | <5% |
| | r.r.: 25% | Time: 1 hr | | |
| | Temp: 800° C. | | | |
| 2 | Rolling | Temp: 800° C. | ~35% | <20% |
| | r.r.: 25% | Time: 1 hr | | |
| | Temp: 800° C. | | | |
| 3 | hot-press sintering | Temp: 800° C. | ~35% | <20% |
| | Temp: 600° C. | Time: 1 hr | | |
| 4 | Rolling | — | ~35% | <25% |
| | r.r.: 40% | | | |
| | Temp: 700° C. | | | |
| 5 | — | Temp: 700° C. | ~35% | <20% |
| | | Time: 3 hr | | |
| 6 | Rolling | — | ~35% | ~35% |
| | r.r.: 25% | | | |
| | Temp: 400° C. | | | |

With reference to Table 1, TA is thermal annealing treatment and TMT is thermal mechanical treatment. According to Table 1, all raw targets had 35% of the compound phase before being treated. After the methods of the present invention as shown in examples 1 to 5, the compound phase of each Cu—Ga alloy sputtering target was apparently reduced. However, the Cu—Ga alloy sputtering target in example 6 was only treated at 400° C., which does not belong to the scope of the present invention, the empirical ratio between the solid-solution and compound phases was not reduced. Therefore, a eutectic system including two phases still existed in the Cu—Ga alloy sputtering target in example 6.

FIG. 3 shows the metallurgical micrograph of example 1, which was take by a microscope, Olympas BH, and was calculated by image measurement software, Image-Pro Plus Version 6.3. Example 1 shows preferable conditions of the method of the present invention. The compound phase is only 5% on the metallographic microstructure of the Cu—Ga alloy sputtering target, so the Cu—Ga alloy sputtering target substantially comprises a single phase.

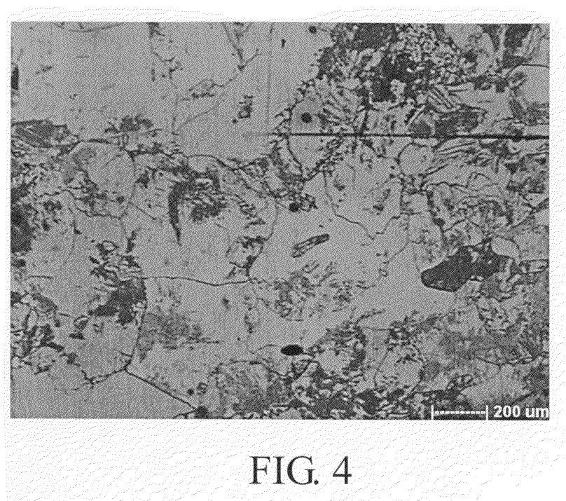

FIG. 4 shows the metallurgical micrograph of example 2, which was take by a microscope, Olympas BH, and was calculated by image measurement software, Image-Pro Plus Version 6.3. The compound phase is 25% on the metallographic microstructure of the Cu—Ga alloy sputtering target. Although the result of example 2 is not as good as example 3, the result shows improvement over example 6.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A copper-gallium alloy sputtering target comprising an alloy, that has 71 atomic % to 78 atomic % of Cu and 22 atomic % to 29 atomic % of Ga, and having a compound phase not more than 25% on its metallographic microstructure.

2. The copper-gallium alloy sputtering target as claimed in claim 1, wherein an average grain size in the alloy of the target is less than 1 mm.

3. A method for fabricating a copper-gallium alloy sputtering target comprising:
forming a raw target;
treating the raw target with at least one thermal mechanical treatment between 500° C.˜850° C., at least one thermal annealing treatment between 500° C.˜850° C. for 0.5˜5 hours or a combination thereof to form a treated target; and
cooling the treated target to a room temperature to obtain the copper-gallium alloy sputtering target that has 71 atomic % to 78 atomic % of Cu and 22 atomic % to 29 atomic % of Ga, and having a compound phase not more than 25% on its metallographic microstructure.

4. The method as claimed in claim 3, wherein the thermal mechanical treatment comprises forging, rolling or hot pressing.

5. The method as claimed in claim 3, wherein a reduction ratio during thermal mechanical treatment is 0˜90%.

6. The method as claimed in claim 3, wherein a reduction ratio during thermal mechanical treatment is 0˜50%.

7. The method as claimed in claim 3, wherein cooling the treated target comprises using air, water or oil.

8. The method as claimed in claim 3, wherein forming the raw target comprises using powder metallurgy or casting.

9. The method as claimed in claim 3, wherein forming the raw target comprises using vacuum melting, continuous casting, centrifugal casting, hot-press sintering, sinter-hot isostatic pressing or hot deforming plasticity.

10. A copper alloy thin film that is deposited with a copper-gallium alloy sputtering target that has 71 atomic % to 78 atomic % of Cu and 22 atomic % to 29 atomic % of Ga and having a compound phase not more than 25% on its metallographic microstructure.

11. The copper alloy thin film as claimed in claim 10, wherein an average grain size in the alloy of the target is less than 1 mm.

12. A solar cell comprising a copper alloy thin film that is deposited with a copper-gallium alloy sputtering target comprising an alloy that has 71 atomic % to 78 atomic % of Cu and 22 atomic % to 29 atomic % of Ga and having a compound phase not more than 25% on its metallographic microstructure.

13. The solar cell as claimed in claim 12, wherein an average grain size in the alloy of the target is less than 1 mm.
